(19) United States
(12) Patent Application Publication
(10) Pub. No.: US 2021/0040956 A1
(43) Pub. Date: Feb. 11, 2021

(54) CENTRIFUGAL FAN

(71) Applicants: MINEBEA MITSUMI Inc., Nagano (JP); TOYOTA BOSHOKU KABUSHIKI KAISHA, Aichi-ken (JP)

(72) Inventors: Haruomi MOROHASHI, Hamamatsu-shi (JP); Koichi TAMAI, Kakegawa-shi (JP); Atsushi TSUZAKI, Toyota-shi (JP)

(21) Appl. No.: 16/985,559

(22) Filed: Aug. 5, 2020

(30) Foreign Application Priority Data
Aug. 8, 2019 (JP) 2019-146166

(51) Int. Cl. F04D 29/42; G01R 31/71; H02K 5/22; H02K 7/14; H02K 11/33; H02K 21/22; F04D 13/02

(52) U.S. Cl. CPC F04D 29/4226; G01R 31/71; H02K 5/225; H02K 7/14; H01R 13/50; H02K 21/22; F04D 13/02; H02K 2211/03; H02K 11/33

(57) ABSTRACT

A centrifugal fan allows good or inferior condition of soldering on the back surface of a circuit board to be visually inspected, includes a secondary casing 130, the secondary casing 130 including a connector housing 190 having opening portion 191 at a lateral side thereof and a connector pin 192 embedded thereinside, wherein one end of the connector pin 192 protrudes inside of the connector housing 190, and the other end of the connector pin 192 penetrates the circuit board 135 and is soldered to the circuit board 135, thereby forming solder fillets 195a and 195b between the front and back surfaces of the circuit board 135 and the connector pin 192, a gap 139 is arranged between the secondary casing 130 and the part of the circuit board 135 where connector pin 192 penetrates, a through hole for visual inspection is arranged in a bottom wall portion of the secondary casing so as to see the fillet formed between the back surface of the circuit board and the connector pin.

### TECHNICAL FIELD

The present invention relates to a centrifugal fan, and in particular, relates to a centrifugal fan in which when a connector pin is soldered to a circuit board, and whether or not soldering was performed properly can be visually inspected by viewing the back side of the circuit board.

### BACKGROUND ART

Conventionally, as this kind of centrifugal fan, a centrifugal fan disclosed in the Patent document 1 is known, for example. In the centrifugal fan of the Patent document 1, during formation of a lower casing 140, a connector housing 161 is formed by integrally forming with resin at the same time. A connector pin 162 is attached inside the connector housing 161, and the connector pin 162 is joined to a wiring pattern of a circuit board 132 arranged at a concave portion 141 of the lower casing 140 by soldering.

Patent document 1 is Japanese Unexamined Patent Application Publication No. 2018-200048 (FIG. 3)

### SUMMARY OF THE INVENTION

Generally, a connector pin 162 is soldered to a through hole formed in a circuit board 132. Due to fused solder, a solder fillet (front fillet) is formed at a corner portion of surface of the circuit board 132 and the connector pin 162. At the same time, part of the fused solder is filled in the through hole, travels to a back side of the circuit board 132 via the through hole, and forms a solder fillet (back fillet), thereby strongly affixing the connector pin 162 to the circuit board 132. Since soldering conditions have an effect on affixing strength of the connector pin 162 and on performance, it is desirable to perform visual inspection of whether or not soldering was performed properly.

However, in the centrifugal fan of Patent document 1, since the connector pin 162 is soldered to the wiring pattern of the circuit board 132 arranged on a bottom surface of the concave portion 141 of the lower casing 140, good or inferior soldering conditions can be visually inspected from a front side (upper surface side) of the circuit board 132; however, it is difficult to visually inspect for good or inferior soldering conditions on the back side of the circuit board 132.

In view of the above circumstances, an object of the present invention is to provide a centrifugal fan in which whether or not soldering was performed properly can be visually inspected at the back side of the circuit board.

The centrifugal fan of the present invention includes a primary casing, a secondary casing cooperating with the primary casing so as to form a casing, an impeller rotatably arranged in the casing, a motor rotating the impeller and a circuit board arranged in the secondary casing, the secondary casing includes a connector housing having an opening portion at lateral side thereof and a connector pin embedded inside, in which one end of the connector pin protrudes inside the connector housing, and the other end of the connector pin protrudes from a bottom surface of the secondary casing, penetrates the circuit board, and is soldered to the circuit board, thereby forming a solder fillet between the front and back surface of the circuit board and the connector pin; there is a gap between the secondary casing and the part of the circuit board where the connector pin penetrates, and a through hole for visual inspection is arranged in a bottom wall portion of the secondary casing so as to see the fillet formed between the back surface of the circuit board and the connector pin.

According to the centrifugal fan of the present invention, since the through hole for visual inspection of which one opening portion is close to the solder fillet of the connector pin existing in the gap and the solder fillet is seen through from the other opening portion is arranged in a bottom wall portion of the secondary casing, the solder fillet can be seen from the secondary casing side through the through hole, and therefore, good or inferior condition of soldering on the back side of the circuit board can be visually inspected.

Here, a surface of the through hole close to the solder fillet can be inclined to a plane orthogonal to the circuit board. In this embodiment, since amount of the secondary casing can be maintained in the inclined portion, the strength can be increased.

An embodiment can be selected in which multiple convex portions protruding to the primary casing side are arranged on the bottom surface of the secondary casing, and the circuit board is supported by the convex portions. In this embodiment, since a gap between the secondary casing and the part of the circuit board where a connector pin penetrates can be wider, visual inspection of the back fillet may be facilitated.

An embodiment can be selected in which a through hole is formed penetrating both the convex portions and the secondary casing, an insulator which is attached on a stator core and is wound in a coil is arranged on the motor, and a pin penetrating the though hole and protruding from the surface of the secondary casing is arranged on the insulator, and the protruding end portion of the pin is swaged so as to be affixed on the surface of the secondary casing. In this embodiment, since thickness along an axial direction of the through hole can be greater, strength around the through hole can be increased.

An embodiment can be selected in which a rib is formed at the bottom surface of the secondary casing made of resin, and the convex portion made of resin and the rib are overlapped in plan view and integrally fused and formed so that the convex portion protrudes from the rib to the primary casing side. In this embodiment, since the convex portion and the rib are overlapped and integrally formed, the rib is reinforced.

It is desirable that an opening portion outside the through hole for visual inspection is closed by a face plate or the like after the inspection of the solder fillet. In this way, dust, water, oil and the like are prevented from entering inside the centrifugal fan.

According to the present invention, a centrifugal fan is provided, in which good or inferior condition of soldering at the back side of the circuit board can be visually inspected.

### BRIEF DESCRIPTION OF THE DRAWINGS

FIG. 1 is a perspective view of the centrifugal fan of the Embodiment.

FIG. 2 is a plan view of the centrifugal fan of the Embodiment.

FIG. 3 is a cross-sectional view cut by A-center-A line in FIG. 2

FIG. 4 is a side view of the centrifugal fan of the Embodiment.

FIG. 5 is a plan view of the lower casing of the Embodiment.

FIG. 6 is a bottom view of the lower casing of the Embodiment.

FIG. 7 is a partially enlarged cross-sectional view of FIG. 3.

### BEST MODE FOR CARRYING OUT THE INVENTION

### [1] Structure of the Centrifugal Fan

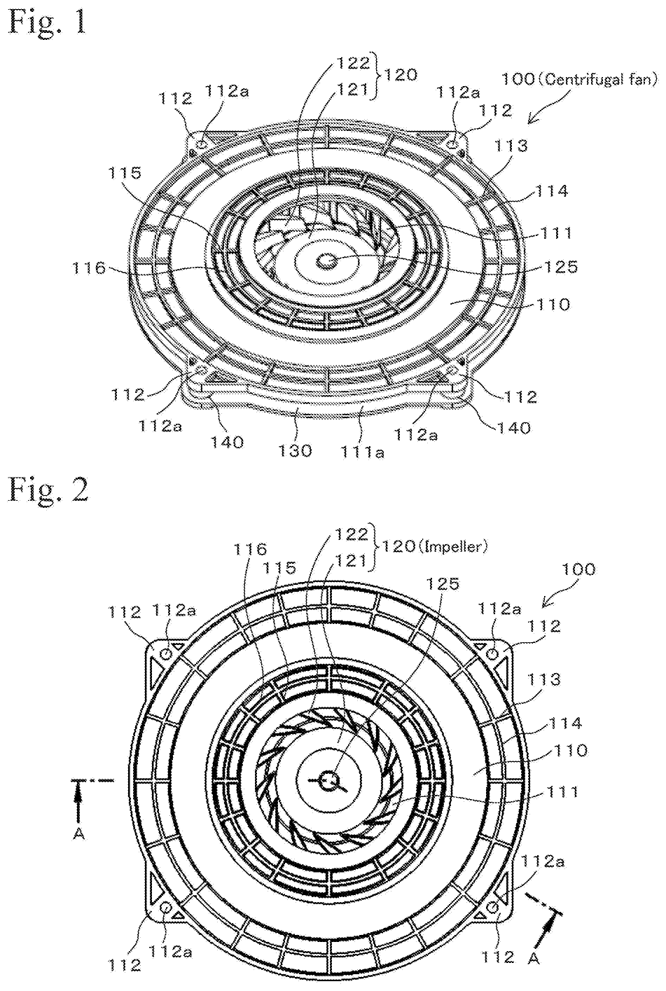

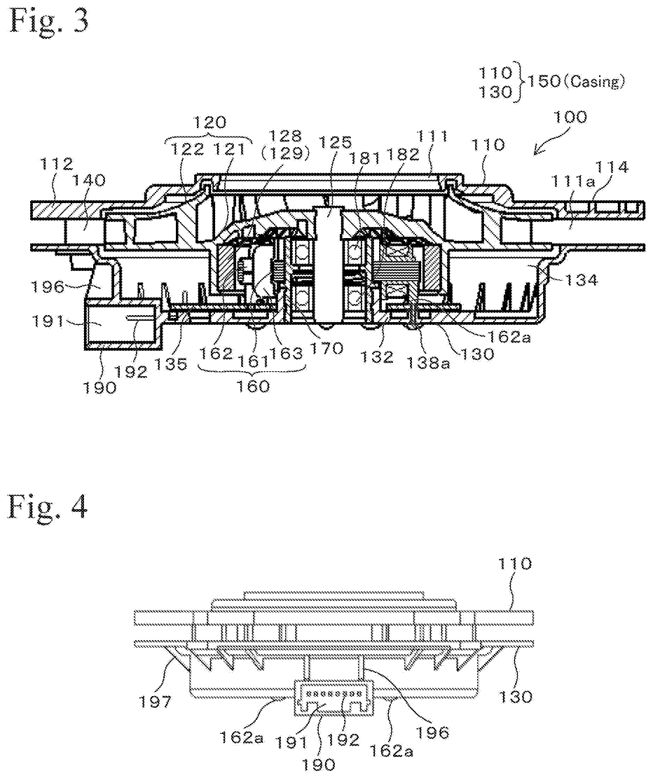

FIG. 1 is a perspective view of a centrifugal fan 100 of the embodiment of the present invention, FIG. 2 is a plan view, and FIG. 3 is a cross-sectional view including a center of a shaft 125, which is a rotation axis. The centrifugal fan 100 includes a casing 150 consisting of an upper casing (primary casing) 110 and a lower casing (secondary casing) 130 being approximately circular plate shaped. It should be noted that in the following explanation of the embodiment, “upper” and “lower” added to a constituent element indicate a direction in FIG. 3 and the like, and they do not determine attitude of the centrifugal fan 100 in actual use.

The upper casing 110 is made of resin, and an air inlet 111 is formed at a center thereof. Furthermore, at four locations along an outer circumference of the upper casing 110, a flange 112, being approximately triangular and projecting to a radially outer direction, is formed. As shown in FIG. 1, on an upper surface of the upper casing 110, radial ribs 113 and a concentric rib 114 are formed at an outer circumferential side, and radial ribs 115 and a concentric rib 116 are formed at inner circumferential side.

On the flange 112, a support pillar 140 extending downwardly in FIG. 3 is integrally formed. It should be noted that another variation can be mentioned in which a counterbore hole is formed at a lower surface of the flange 112, the support pillar 140 is engaged therein, and they are attached by an adhesive or the like. The upper casing 110 and the lower casing 130 are combined with each other by the support pillar 140.

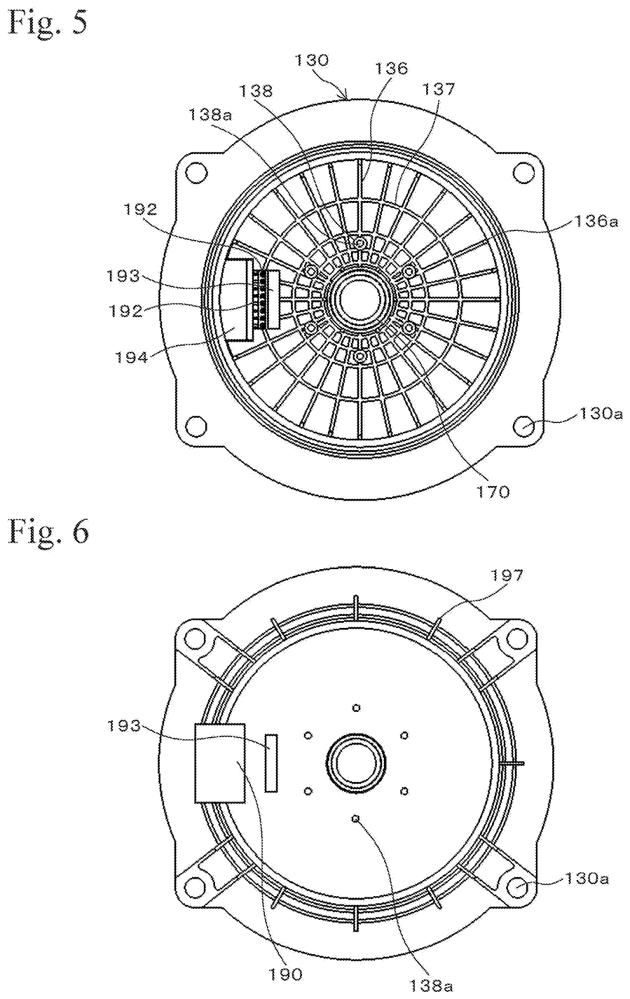

In this embodiment, a through hole 112a is formed in the flange 112 and the support pillar 140, a lower end surface of the support pillar 140 contacts a bottom surface of the lower casing 130, a screw (not shown) is inserted in a through hole 130a (shown only in FIGS. 5 and 6) formed in the lower casing 130, and the screw is screwed in the through hole 112a of the support pillar 140, so that the upper casing 110 and the lower casing 130 are combined via the support pillar 140. It should be noted that another variation can be mentioned in which a boss is formed on the lower surface of the support pillar 140, the boss is inserted in the through hole 130a of the lower casing 130, and a top of the boss protruding from the through hole 130a is plastically deformed by heat swaging or IR swaging so as to combine them.

A portion of the side surface of the casing 150 excluding the support pillar 140 is a gap between the upper casing 110 and the lower casing 130, and this gap portion corresponds to an air outlet 111a. In addition, an impeller 120 made of resin is contained in a rotatable condition between the upper casing 110 and the lower casing 130.

The impeller 120 consists of a hub 121 having a cup shape, and multiple blades 122 which incline from around the outer circumference of the upper surface of the hub 121 to a radial direction and which extend outwardly. All of the blades 122 have the same shape, and they are arranged at equal spacing along a circumferential direction. That is, the blades 122 rotate clockwise in FIG. 2, and air is blown out in a radially outward direction.

A ring shaped yoke (not shown) and a ring shaped magnet 128 (shown only in FIG. 3), being a rotor magnet, are arranged on an inner circumferential surface of a cylindrical portion of the impeller 120. A stator core 161 is arranged inside (axially central side) of the ring shaped magnet 128 via a spacing. The stator core 161 is made by layering thin tabular soft magnetic material such as electromagnetic steel plate or the like, has a ring shape, and has multiple salient poles arranged on an outer circumference thereof.

An insulator 162, which is made of resin and which has an upward and downward half-divided structure, is attached on the stator core 161, and a stator coil 163 is wound on each salient pole of the stator core 161 via the insulator 162.

The lower casing 130 is made of resin and a dish shaped structure and has a concave portion 134. A circuit board 135 is contained in the concave portion 134. The circuit board 135 includes a driving circuit supplying a driving current to the stator coil 163. Structures of the circuit board 135 and therearound are explained as follows in detail.

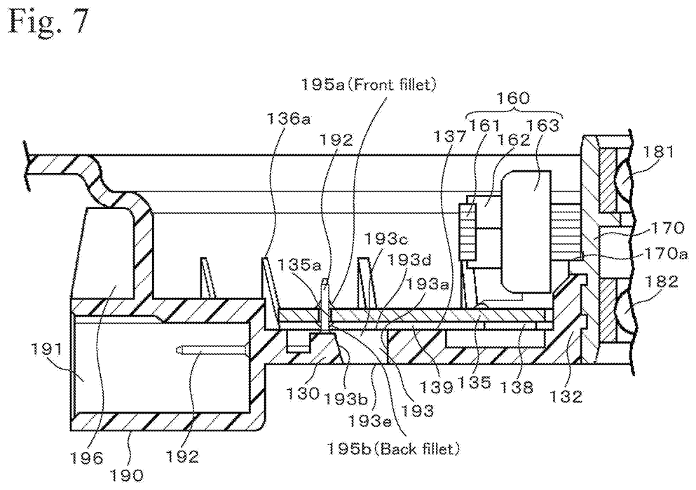

A cylindrical portion 132 protruding upwardly is formed at a central part of the lower casing 130. In the cylindrical portion 132, a bearing holder (bearing holding portion) 170 which is made of metal (for example, brass) and is cylindrical, is affixed by an insert molding. The abovementioned stator core 161 is attached to the outer circumference of the bearing holder 170. A step portion 170a (see FIG. 7) is arranged on the outer circumferential surface of the bearing holder 170, and an inner circumferential portion of the stator core 161 is placed on this step portion 170a.

The stator core 161, the insulator 162, and the stator coil 163 form a stator 160. Furthermore, a shaft 125, the ring shaped yoke (not shown), and the magnet 128 form a rotor 129. In this way, the stator 160 and the rotor 129 form an outer rotor type brushless DC motor.

As shown in FIG. 3, in the bearing holder 170, a pair of a ball bearings 181 and 182 are arranged in a condition so as to be mutually separated vertically, and the shaft 125 is supported by the ball bearings 181 and 182 rotatably. The shaft 125 is integrally formed by an insert molding with the hub 121 of the impeller 120. Therefore, the impeller 120 rotates together with the rotor 129.

### [2] Structure around the Circuit Board

The structure around the circuit board 135 is explained with reference to FIGS. 4 to 7.

As shown in FIG. 5, multiple radial ribs 136 and concentric ribs 137 are formed on the bottom surface of the lower casing 130. As shown in FIG. 7, a triangular rib 136a is formed at the end portion of outer circumferential side of the radial rib 136. Furthermore, a convex portion 138 which is circular in plan view is overlapped with the radial rib 136 and concentric rib 137 in plan view, and they are integrally fused and formed at around the center of the lower casing 130. The convex portion 138 protrudes from the radial rib 136 and the concentric rib 137 to the upper casing 110 side.

A through hole 138a which penetrates to the back surface of the lower casing 130 is formed at the convex portion 138. In addition, the circuit board 135 is supported by the convex portion 138, and the radial rib 136 together with the concentric rib 137 have a gap 139 between them and the circuit board 135.

On the other hand, as shown in FIG. 3, a resin pin 162a protruding downwardly is formed at the insulator 162 of lower side. The resin pin 162a has a small diameter portion at which a diameter is smaller than that of base portion, at the top portion thereof. By inserting the small diameter portion into a through hole (not shown) formed at the circuit board 135 and the through hole 138a formed at the convex portion 138, and by deforming the top portion of the small diameter portion protruding from the through hole 138a by a method such as heat swaging or IR swaging, the resin pin 162a is attached to the lower casing 130. In addition, by contacting a step portion which is boundary of the base portion and the small diameter portion on the circuit board 135, upward movement of the circuit board 135 is blocked.

As shown in FIG. 7, a connector housing 190 is integrally formed with the lower casing 130 at a lateral side of the lower casing 130. The connector housing 190 is rectangular in side view, and an opening portion 191 is formed at a side surface thereof. One of the end portions of multiple connector pins 192, which are integrally formed with the lower casing 130 by an insert molding, protrude inside of the connector housing 190. The connector pin 192 has a shape of the letter L, and the other end portions thereof extend upwardly, penetrate through holes 135a formed in the circuit board 135 and protrude. Then, the connector pins 192 are soldered to the circuit board 135 and are connected with the driving circuit wired on the circuit board 135.

FIG. 7 shows a solder fillet (front fillet) 195a which is formed by fused solder accumulated at a corner portion between the connector pin 192 and surface of the circuit board 135, and a solder fillet (back fillet) 195b which is formed by fused solder flowing into the through hole 135a of the circuit board 135 and accumulated at a corner portion between the connector pin 192 and back surface of the circuit board 135.

At the bottom wall portion of the lower casing 130, a through hole for visual inspection 193 is formed close to the connector pin 192. The through hole for visual inspection 193 is formed by a perpendicular surface 193a which is perpendicular to the circuit board 135, an inclined surface 193b which is inclined to the perpendicular surface 193a, and a side surface 193c which is perpendicular to the inclined surface 193b. In this case, the inclined surface 193b directs and descends to a direction opposite to the connector pin 192 side.

An opening portion 193d which is inside the through hole for visual inspection 193 is close to the back fillet 195b, and the back fillet 195b is seen through from an opening portion 193e which is outside the through hole. It should be noted that the reference numeral 196 is a rib for reinforcing the connector housing 190, and the reference numeral 197 is a triangular rib.

### [3] Action of the Embodiment

As shown in FIG. 7, since the back fillet 195b is arranged in addition to the gap 139 arranged between the circuit board 135 and the radial rib 136 together with the concentric rib 137, and furthermore, since the opening portion for visual inspection 193 is formed, the condition of the back fillet 195b formed at the connector pin 192 can be visually inspected.

Since the back fillet 195b and the front fillet 195a sandwich the circuit board 135 so that the connector pin 192 is strongly affixed to the circuit board 135, performance of the connector pin 192 can be maintained. It should be noted that inspection of the front fillet 195a is performed from the upper side of the lower casing 130. In this way, in the above embodiment, since it is made so that it is possible to see through from the opening portion 193b side which is outside the through hole for visual inspection 193 to the back fillet 195b of the connector pin 192, the solder fillet (back fillet) 195b can be visually inspected, and good or inferior condition of soldering at the back side of the circuit board 135 can be visually inspected. It should be noted that the opening portion 193e outside the through hole for visual inspection 193 is closed by a face plate or the like after finishing the inspection of the solder fillet (back fillet) 195b.

In the above embodiment, since the inclined surface 193b which directs and descends to a direction opposite to the connector pin 192 side is arranged in the through hole for visual inspection 193, amount of the lower casing is maintained in the inclined portion, and the strength is increased.

In the above embodiment, since the multiple convex portions 138 upwardly protruding are arranged on the bottom surface of the lower casing 138, and the circuit board 135 is supported by the convex portions 138, a gap between the lower casing 130 and the part of the circuit board 135 where the connector pin 192 penetrates can be wider, visual inspection of the back fillet may be facilitated.

In the above embodiment, the through hole 138a is formed penetrating both of the convex portion 138 and the lower casing 130, and on the other hand, the resin pin 162a penetrating the through hole 138a and protruding from the back surface of the lower casing 130 is formed on the insulator 162 and the end portion of the resin pin 162a protruding is swaged so as to be affixed to the back surface of the lower casing 130. Therefore, the thickness of the through hole 138a along the axial direction is large, and therefore, strength around the through hole 138a is higher.

In the above embodiment, since the radial rib 136 and the concentric rib 137 are formed on the bottom surface of the lower casing 130, and the convex portion 138 overlaps the ribs 136 and 137 in plan view, and they are integrally fused and formed, the strength of the ribs 136 and 137 is increased.

### [4] Variations

(1) In the above embodiment, a cross-sectional shape of the through hole for visual inspection 193 is rectangle. Alternatively, it can be ellipse or oval. In addition, a through hole for visual inspection having circular or rectangular cross-section or the like can be formed at a position corresponding to each of the connector pins 192.

(2) In the above embodiment, the rotor magnet 128 is attached to the hub 121 of the impeller 120. Alternatively, the present invention may be applied to a structure in which a metallic bush (for example, made of brass) is affixed to the shaft 125 by press fitting or the like, a yoke made of a soft magnetic material (for example, iron) is attached to the bush by swaging or the like, the rotor magnet is attached to the yoke, and the yoke is attached to the impeller.

The present invention may be used in a technical field of a centrifugal fan, such as a blower device used for cooling, ventilation, air conditioning of home electric appliances, office automation equipment and industrial equipment, and vehicle equipment, and the like.

### EXPLANATION OF REFERENCE NUMERALS

100: centrifugal fan, 110 upper casing (primary casing), 111: air inlet, 111a: air outlet, 112: flange, 112a: through hole, 113: radial rib, 114 concentric rib, 115: radial rib, 116: concentric rib, 120: impeller, 121: hub, 122: blade, 125: shaft, 128: magnet, 129: rotor, 130: lower casing (secondary casing), 130a: through hole, 132: cylindrical portion, 134: concave portion, 135: circuit board, 135a: through hole, 136: radial rib, 136a: triangular rib, 137: concentric rib, 138: convex portion, 138a: through hole, 139: gap, 140: support pillar, 150: casing, 160: stator, 161: stator core, 162: insulator, 162a: resin pin, 163 stator coil, 170: bearing holder, 170a: step portion, 181: ball bearing, 182: ball bearing, 190: connector housing, 191: opening portion, 192: connector pin, 193: through hole for visual inspection, 193a: perpendicular surface, 193b: inclined surface, 193c: side surface, 193d: inner opening portion, 193e: outer opening portion, 195a: front fillet, 195b: back fillet, 196: rib, 197: rib.

What is claimed is:

1. A centrifugal fan comprising:
a primary casing,
a secondary casing cooperating with the primary casing so as to form a casing,
an impeller rotatably arranged in the casing,
a motor for rotating the impeller, and
a circuit board arranged in the secondary casing,
the secondary casing comprising:
a connector housing having an opening portion at a lateral side thereof, and
a connector pin embedded inside,
wherein one end of the connector pin protrudes inside of the connector housing, and the other end of the connector pin protrudes from a bottom surface of the secondary casing, penetrates the circuit board, and is soldered to the circuit board, thereby forming a solder fillet between the front and back surfaces of the circuit board and the connector pin,
a gap is between the secondary casing and the part of the circuit board where connector pin penetrates,
a through hole for visual inspection is arranged in a bottom wall portion of the secondary casing so as to see the fillet formed between the back surface of the circuit board and the connector pin.

2. The centrifugal fan according to claim 1, wherein a surface of the through hole for visual inspection close to the solder fillet is inclined to a plane orthogonal to the circuit board.

3. The centrifugal fan according to claim 1, wherein multiple convex portions protruding to the primary casing side are arranged at the bottom surface of the secondary casing, and the circuit board is supported by the convex portions.

4. The centrifugal fan according to claim 3, wherein a through hole is formed penetrating both the convex portions and the secondary casing,
an insulator which is attached on a stator core and is wound in a coil and is arranged on the motor, and
a pin penetrating the though hole and protruding from the surface of the secondary casing is arranged on the insulator, and the protruding end portion of the pin is swaged so as to be affixed at the surface of the secondary casing.

5. The centrifugal fan according to claim 3, wherein a rib is formed at the bottom surface of the secondary casing made of resin, and the convex portion made of resin and the rib are overlapped in plan view and integrally fused and formed so that the convex portion protrudes from the rib to the primary casing side.

6. The centrifugal fan according to claim 1, wherein an opening portion outside the through hole for visual inspection is closed by a closing member.
